(19) United States
(12) Patent Application Publication
(10) Pub. No.: US 2026/0181126 A1
(43) Pub. Date: Jun. 25, 2026

(54) CURVE STEREOSCOPIC DISPLAY AND METHOD OF MANUFACTURING THE SAME

(71) Applicant: INDUSTRIAL TECHNOLOGY RESEARCH INSTITUTE, HSINCHU (TW)

(72) Inventors: Jane-Hway LIAO, Hsinchu City (TW); Keng-Hsien LIN, Tainan City (TW); Ming-Chin LI, Taichung City (TW); Yi-Hao PENG, Taipei City (TW); Li-Ying WANG HE, New Taipei City (TW); Szu-Wei WU, Taoyuan City (TW)

(21) Appl. No.: 19/079,488

(22) Filed: Mar. 14, 2025

(30) Foreign Application Priority Data
Dec. 24, 2024 (TW) 113150394

(51) Int. Cl. H04N 13/32; H04N 13/31; H04N 13/327; H05K 1/02; H05K 1/18

(52) U.S. Cl. CPC H04N 13/32; H04N 13/31; H04N 13/327; H05K 1/0283; H05K 1/189; H05K 2201/10106

(57) ABSTRACT

A curve stereoscopic display includes a target carrier, a light-emitting layer, and a parallax barrier. A normal direction of a first zone of the surface is different from a normal direction of a second zone. The light-emitting layer includes a flexible substrate covering the target carrier and light-emitting units disposed on the flexible substrate. The light-emitting units include a first group of light-emitting units on the first zone and a second group of light-emitting units on the second zone. The parallax barrier is disposed on the light-emitting layer and includes optical lenses. The optical lenses includes a first optical lens that is configured to adjust a light path of the first group of light-emitting units and a second optical lens that is configured to adjust a light path of the second group of light-emitting units. The diopters of the first optical lens and the second optical lens are different.

### CROSS-REFERENCE TO RELATED APPLICATION

This application claims priority to Taiwan Application Serial Number 113150394, filed Dec. 24, 2024, which is herein incorporated by reference in its entirety.

### BACKGROUND

### Field of Invention

The present disclosure relates to a curve stereoscopic display and a method of manufacturing the same.

### Description of Related Art

With the development of industry, curve displays have been widely utilized in different fields of daily life. However, it is difficult to display stereoscopic image using the curve display. Meanwhile, the visible range of the curve display is reduced thereby resulting in the failure of stereoscopic image display.

### SUMMARY

An aspect of the disclosure provides a curve stereoscopic display. The curve stereoscopic display includes a target carrier, a light-emitting layer, and a parallax barrier. The target carrier has a surface having a first zone and a second zone, wherein a normal direction of the first zone is different from a normal direction of the second zone. The light-emitting layer includes a flexible substrate covering the surface of the target carrier and a plurality of light-emitting units disposed on the flexible substrate. Each of the light-emitting units includes a light-emitting component and a packaging structure on the light-emitting component, and the light-emitting units include a first group of light-emitting units on the first zone and a second group of light-emitting units on the second zone. The parallax barrier is disposed on the light-emitting layer, wherein the parallax barrier includes a plurality of optical lenses. The optical lenses include a first optical lens on the first zone and a second optical lens on the second zone, wherein the first optical lens is configured to adjust a light path of the first group of light-emitting units, and the second optical lens is configured to adjust a light path of the second group of light-emitting units. A diopter of the first optical lens is different from a diopter of the second optical lens.

Another aspect of the disclosure provides a method of manufacturing a curve stereoscopic display. The method includes obtaining a surface profile of a target carrier, wherein the surface profile includes a non-planar plane; dividing the surface profile into a plurality of zones; disposing a light-emitting layer, based on the zones, the light-emitting layer includes a flexible substrate and a plurality of light-emitting units disposed on the flexible substrate, wherein each of the light-emitting units includes a light-emitting component and a packaging structure on the light-emitting component; disposing a parallax barrier, wherein the parallax barrier includes a plurality of optical lenses, and diopters of the optical lenses are designed based on the zones; and covering the light-emitting layer and the parallax barrier on a surface of the target carrier.

It is to be understood that the foregoing general description and the following detailed description are by examples, and are intended to provide further explanation of the disclosure as claimed.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain the principles of the disclosure.

FIG. 1 is a partial schematic view of a curve stereoscopic display according to some embodiments of the disclosure.

FIG. 2A and FIG. 2B are partial cross-sectional views of the curve stereoscopic display before and after being stretched according to some embodiments of the disclosure, respectively.

FIG. 3 is a partial cross-sectional view of the curve stereoscopic display according to some embodiments of the disclosure.

FIG. 4 is a partial cross-sectional view of the curve stereoscopic display according to some other embodiments of the disclosure.

FIGS. 5A, 5B, 6A, and 6B are oblique views and corresponding simulation light fields of the packaging structure of the curve stereoscopic display according to different embodiments of the disclosure.

FIGS. 7A and 7B are optical simulation views of the optical lens of the curve stereoscopic display according to different embodiments of the disclosure.

FIG. 8 is a partial cross-sectional view of the curve stereoscopic display according to some embodiments of the disclosure.

FIG. 9 is a partial top view of the light-emitting layer of the curve stereoscopic display according to some embodiments of the disclosure.

FIG. 10 is a partial cross-sectional view of the light-emitting layer of the curve stereoscopic display according to some embodiments of the disclosure.

FIG. 11A and FIG. 11B are partial top view and cross-sectional view of the light-emitting layer of the curve stereoscopic display according to some embodiments of the disclosure, respectively.

FIG. 12 is a flow chart of a method of manufacturing the curve stereoscopic display according to some embodiments of the disclosure.

FIG. 13 is a flow chart of a method of manufacturing the curve stereoscopic display according to some other embodiments of the disclosure.

### DESCRIPTION OF THE EMBODIMENTS

Reference will now be made in detail to the present embodiments of the disclosure, examples of which are illustrated in the accompanying drawings. Wherever possible, the same reference numbers are used in the drawings and the description to refer to the same or like parts.

Further, spatially relative terms, such as “on,” “over,” “under,” “between” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

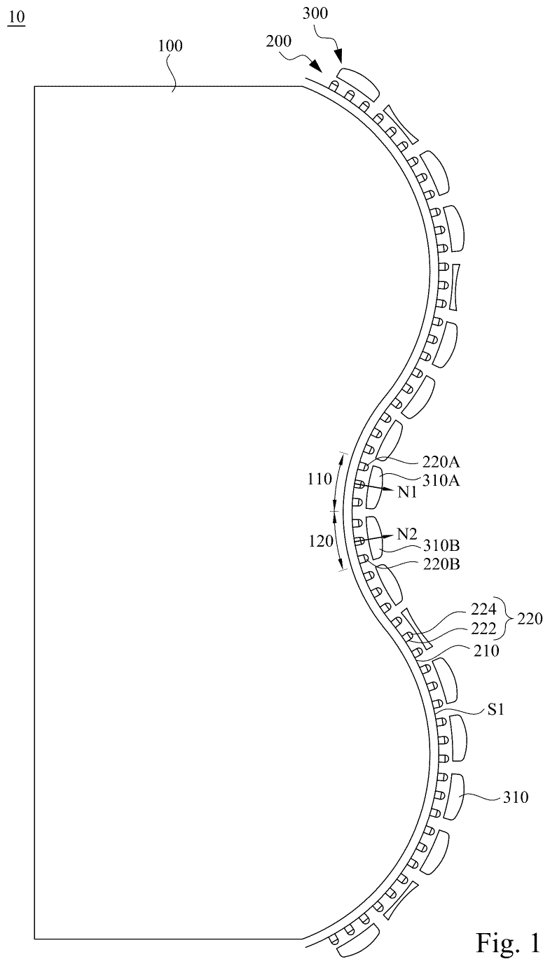

Reference is made to FIG. 1, which is a partial schematic view of a curve stereoscopic display according to some embodiments of the disclosure. The curve stereoscopic display 10 includes a target carrier 100, a light-emitting layer 200 disposed on the target carrier 100, and a parallax barrier 300 disposed on the light-emitting layer 200. In some embodiments, the target carrier 100 includes a non-planar surface S1, the light-emitting layer 200 conformally covers the surface S1 of the target carrier 100, and the parallax barrier 300 also conformally covers the light-emitting layer 200. The light-emitting layer 200 is configured to provide a project image, and the parallax barrier 300 is configured to separate the project image into a left-eye image and a right-eye image to achieve the stereoscopic display function.

For example, the non-planar surface S1 can be divided into a plurality of zones including a first zone 110 and a second zone 120, in which a normal direction N1 of the first zone 110 is different from a normal direction N2 of the second zone 120. The first zone 110 and the second zone 120 can be adjacent or not adjacent.

The light-emitting layer 200 includes a flexible substrate 210 and a plurality of light-emitting units 220 disposed on the flexible substrate 210. Each of the light-emitting units 220 includes at least one light-emitting component 222 and a packaging structure 224 disposed on the light-emitting component 222. In some embodiments, the material of the flexible substrate 210 can be polyimide (PI), silicone, polycarbonate (PC), or thermoplastic polyurethane (TPU), etc. In some embodiments, the material of the flexible substrate 210 can be elastomers such as styrene-ethylene/butylene-styrene (SEBS). In some embodiments, the material of the flexible substrate 210 can be thermoplastic elastomers (TPE) such as TPESEBS. In some embodiments, the material of the flexible substrate 210 can be polyurethane (PU), modified polylactic acid (PLA), or modified polypropylene (PP). In some embodiments, the material of the flexible substrate 210 can be shape memory polymer (SMP), hydrogels, or nano-composite elastomers, etc. The material of the flexible substrate 210 of the disclosure can be selected from either one or combinations of above. In some embodiments, the Young's module of the flexible substrate 210 is in a range between 1 MPa to 20 GPa, but the disclosure is not limited to.

In some embodiments, the light-emitting components 222 can be electroluminescence (EL), quantum dot (QD), organic light-emitting diode (OLED), micro light-emitting diode (micro LED), or flexible hybrid electronics (FHE), but the disclosure is not limited to.

In some embodiments, the shape of each of the packaging structures 224 is defined according to the light-emitting angle of its location. The light-emitting angle of the packaging structure 224 is more converged when the packaging structure 224 includes a convex structure. The light-emitting angle of the packaging structure 224 is more diverged when the packaging structure 224 includes a concave structure. By adjusting the shape of each of the packaging structures 224, the light-emitting uniformity of different zones of the curve stereoscopic display 10 can be improved, thereby enhancing the display quality of the curve stereoscopic display 10. The packaging structures 224 can be one-to-one or one-to-more disposed on each of the light-emitting components 222.

The parallax barrier 300 is disposed on the light-emitting layer 200, and the parallax barrier 300 includes a plurality of optical lenses 310. The light-emitting angle of the light emitted by the light-emitting components 222 is adjusted by the one or more packaging structures 224, and the adjusted light-emitting angle of the light is the insert light angle of the optical lenses 310 of the parallax barrier 300. The diopters of the optical lenses 310 are designed based on requirements of different zones. For example, the optical lens 310 having positive diopter provides light converge function, and the optical lens 310 having negative diopter provides light diverge function. The parallax barrier 300 is configured to guide the lights to the predetermined image paths, which may solve the problem of failure or twist stereoscopic image of the curve stereoscopic display.

In some embodiments, the material of the parallax barrier 300 can be light sensitive photoresist material, transparent organic or inorganic material (such as organic or inorganic material with light transmission greater than 40%), or other suitable materials with higher transmission. In some embodiments, the parallax barrier 300 can be made by photoresist molding, etching, or laser drilling, etc.

Reference is still made to FIG. 1. The light-emitting units 220 include a first group of light-emitting units 220A disposed on the first zone 110 and second group of light-emitting units 220B disposed on the second zone 120. The optical lenses 310 include a first optical lens 310A on the first zone 110 and a second optical lens 310B on the second zone 120. The diopter of the first optical lens 310A is different from the diopter of the second optical lens 310B based on different located zones, such that the first optical lens 310A is configured to adjust the light path of the first group of light-emitting units 220A, and the second optical lens 310B is configured to adjust the light path of the second group of light-emitting units 220B. As a result, the light paths of the first group of light-emitting units 220A on the first zone 110 with the normal direction N1 and the second group of light-emitting units 220B on the second zone 120 with the normal direction N2 different from the normal direction N1 can be guided to the predetermined image paths.

Additionally, the light-emitting layer 200 and the parallax barrier 300 may be adhered on the surface S1 of the target carrier 100, and the surface S1 of the target carrier 100 includes a non-planar surface, the light-emitting layer 200 and the parallax barrier 300 may be stretched along the surface S1 of the target carrier 100 during adhering the light-emitting layer 200 and the parallax barrier 300. Therefore, the relative position between the light-emitting units 220 of the light-emitting layer 200 and the optical lenses 310 of the parallax barrier 300 may be maintained. It is noted that in order to clearly, the target carrier with non-planar surface is not illustrated, and the light-emitting layer 200 and the parallax barrier 300 are illustrated based on a plane.

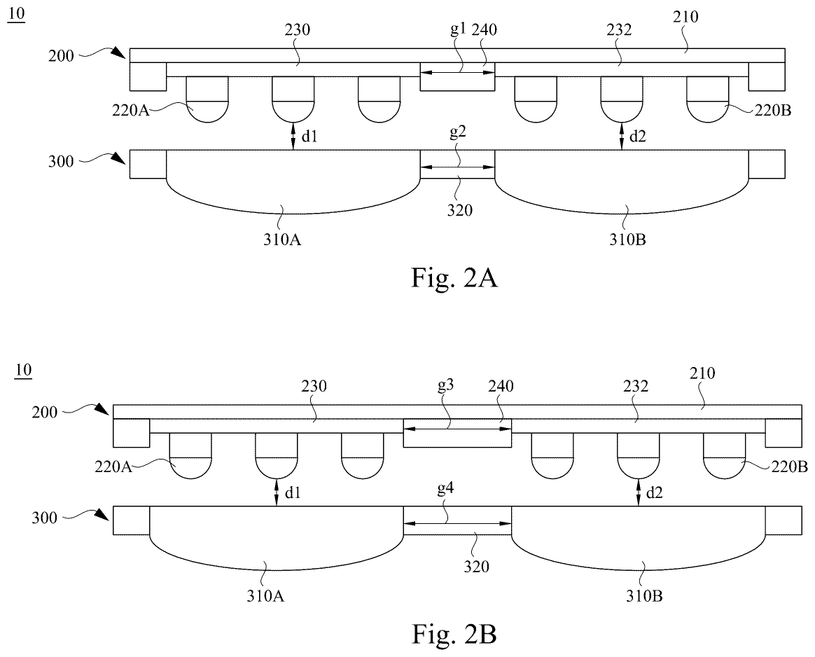

Reference is made to FIG. 2A and FIG. 2B, which are partial cross-sectional views of the curve stereoscopic display before and after being stretched according to some embodiments of the disclosure, respectively. In some embodiments, the light-emitting layer 200 further includes a first control board 230 and a second control board 232 disposed on the flexible substrate 210. The first group of light-emitting units 220A is disposed on the first control board 230, and the second group of light-emitting units 220B is disposed on the second control board 232. The light-emitting layer 200 further includes a first elastic piece 240 configured to interconnect the first control board 230 and the second control board 232.

The parallax barrier 300 further includes a second elastic piece 320 configured to interconnect the first optical lens 310A and the second optical lens 310B. The material of the second elastic piece 320 of the parallax barrier 300 has the same or similar characteristic of the material of the first elastic piece 240 of the light-emitting layer 200 so that the first elastic piece 240 and the second elastic piece 320 have identical stretching ratio.

For example, as shown in FIG. 2A, before the light-emitting layer 200 and the parallax barrier 300 are stretched, a first gap g1 is defined between the first control board 230 and the second control board 232, in which the first gap g1 can be represented as the width of the first elastic piece 240 between the first control board 230 and the second control board 232. A second gap g2 is defined between the first optical lens 310A and the second optical lens 310B, in which the second gap g2 can be represented as the width of the second elastic piece 320 between the first optical lens 310A and the second optical lens 310B. The first gap g1 is equal to the second gap g2 before the light-emitting layer 200 and the parallax barrier 300 are stretched.

Then, as shown in FIG. 2B, after the light-emitting layer 200 and the parallax barrier 300 are stretched, a third gap g3 is defined between the first control board 230 and the second control board 232, in which the third gap g3 can be represented as the width of the stretched first elastic piece 240 between the first control board 230 and the second control board 232. A fourth gap g4 is defined between the first optical lens 310A and the second optical lens 310B, in which the fourth gap g4 can be represented as the width of the stretched second elastic piece 320 between the first optical lens 310A and the second optical lens 310B. The stretching amount of the first elastic piece 240 is equal to the stretching amount of the second elastic piece 320 after the light-emitting layer 200 and the parallax barrier 300 are stretched. The third gap g3 is equal to the fourth gap g4 and is greater than or equal to the first gap g1 or the second gap g2. Accordingly, the relative position between the light-emitting units 220 of the light-emitting layer 200 and the optical lenses 310 of the parallax barrier 300 can be maintained, before and after stretching the light-emitting layer 200 and the parallax barrier 300. For example, the relative position between the first group of light-emitting units 220A and the first optical lens 310A and the relative position between the second group of light-emitting units 220B and the second optical lens 310B are maintained. In some embodiments, a first distance d1 between the first group of light-emitting units 220A and the first optical lens 310A and a second distance d2 between the second group of light-emitting units 220B and the second optical lens 310B are the same before and after the light-emitting layer 200 and the parallax barrier 300 are stretched.

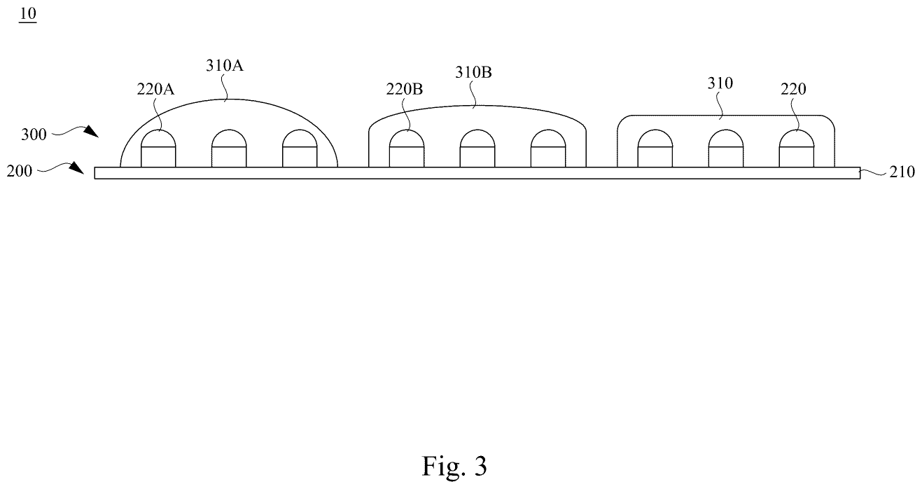

Reference is made to FIG. 3, which is a partial cross-sectional view of the curve stereoscopic display according to some embodiments of the disclosure. In some embodiments, the optical lenses 310 of the parallax barrier 300 are directly covered on the surface of the flexible substrate 210 of the light-emitting layer 200, and the optical lenses 310 cover corresponding group of the light-emitting units 220. For example, the first optical lens 310A is formed on the surface of the flexible substrate 210 of the light-emitting layer 200 and covers the first group of light-emitting units 220A, and the second optical lens 310B is formed on the surface of the flexible substrate 210 of the light-emitting layer 200 and covers the second group of light-emitting units 220B. Therefore, the relative position between the light-emitting units 220 of the light-emitting layer 200 and the optical lenses 310 of the parallax barrier 300 can be also maintained, before and after stretching the light-emitting layer 200 and the parallax barrier 300.

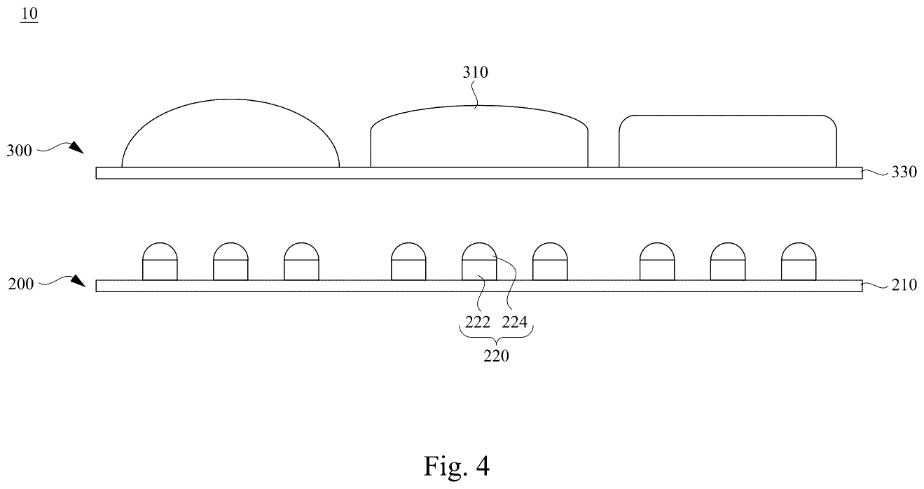

Reference is made to FIG. 4, which is a partial cross-sectional view of the curve stereoscopic display according to some other embodiments of the disclosure. In some embodiments, the parallax barrier 300 includes a stretchable substrate 330. The material of the stretchable substrate 330 of the parallax barrier 300 has the same or similar characteristic of the material of the flexible substrate 210 of the light-emitting layer 200 so that the stretchable substrate 330 and the flexible substrate 210 have identical stretching ratio, thereby achieving the purpose of maintaining the relative position between the light-emitting units 220 of the light-emitting layer 200 and the optical lenses 310 of the parallax barrier 300 before and after stretching the light-emitting layer 200 and the parallax barrier 300. In some embodiments, comparing to the flexible substrate 210, the stretchable substrate 330 further includes a circuit layer (not shown) to drive the light-emitting components 222.

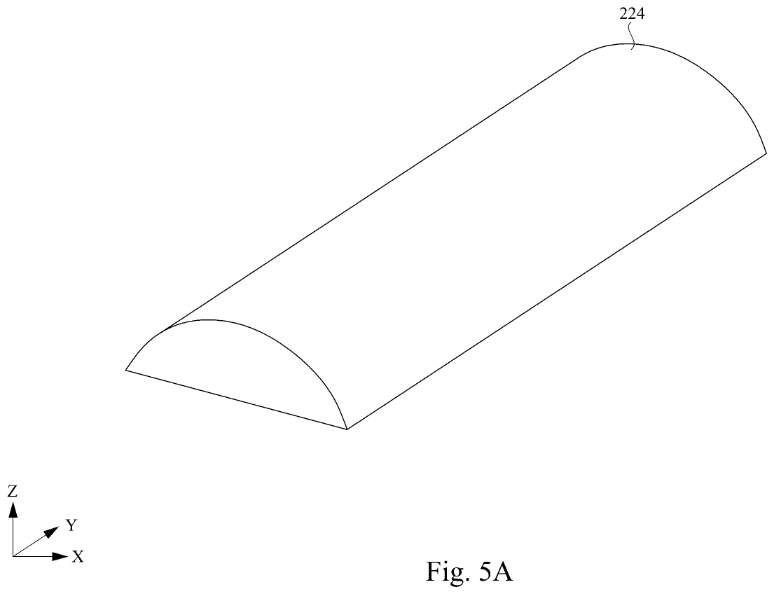

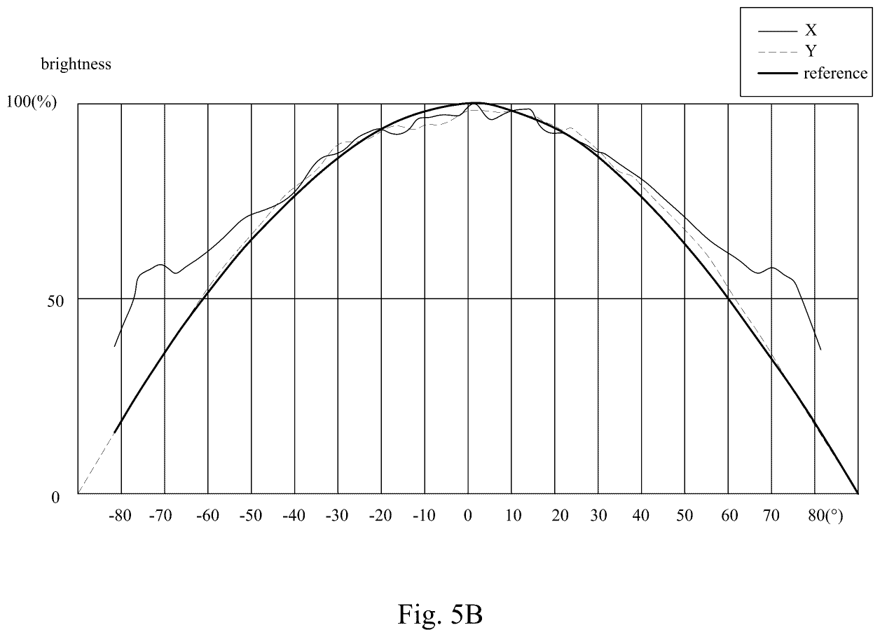

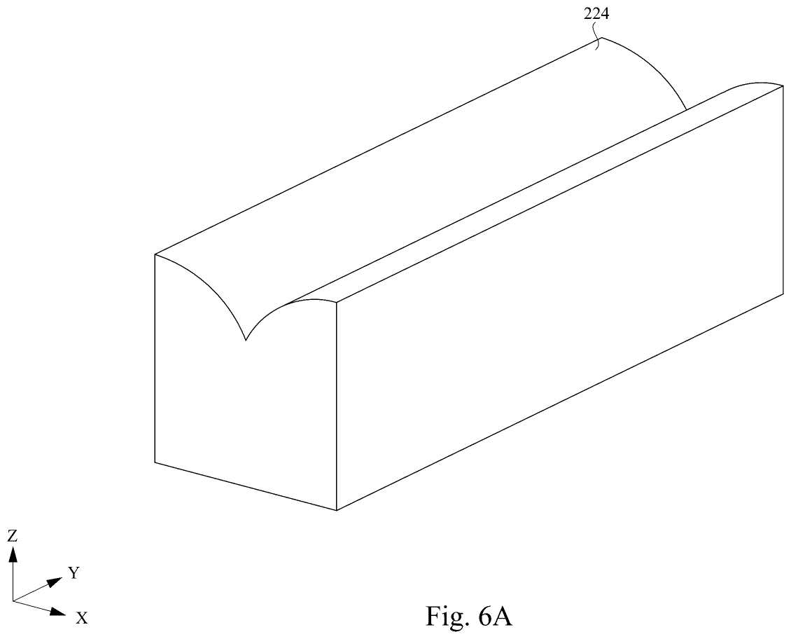

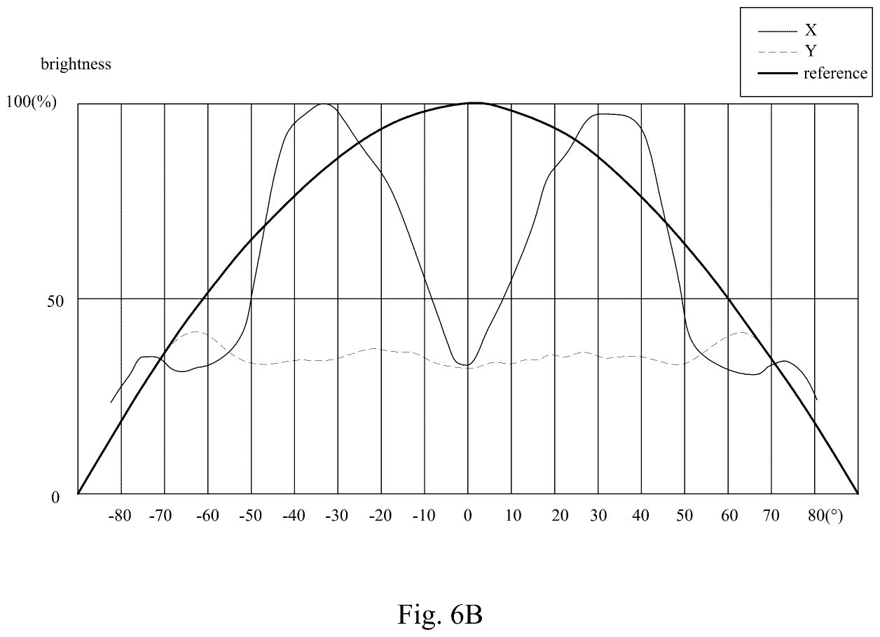

Reference is made to FIGS. 5A, 5B, 6A, and 6B, which are oblique views and corresponding simulation light fields of the packaging structure of the curve stereoscopic display according to different embodiments of the disclosure. In some embodiments, the material of the packaging structure 224 is an organic material, and the shape of the packaging structure 224 is defined by a series of lithography processes. For example, a photoresist applying process is performed to layer the packaging structure 224 as predetermined (including using software to output cross-sectional files). A maskless exposure apparatus is set to perform multilayer laser exposure, and a fine etching process is further performed to define the packaging structure 224 with the predetermined shape. In some embodiments, the material of the packaging structure 224 is suitable to be utilized in molding material or transparent organic material or inorganic material such as glass. In some embodiments, the packaging structure 224 can be fabricated by a laser drilling, and the material of the packaging structure 224 is a laser-absorbable material which can be patterned by the laser drilling process. The material of the packaging structure 224 is preferable transparent. In some embodiments, the packaging structure 224 can be fabricated by a laser process followed by molding process, and the material of the packaging structure 224 can be molding material, but the disclosure is not limited to.

As shown in FIG. 5A, the packaging structure 224 is a half-cylinder symmetric along y-axis and has a convex surface along the x-axis. The corresponding simulation light field is shown in FIG. 5B. The view of angle of the packaging structure 224 of FIG. 5A is in a range from about −75 degrees to about +75 degrees, in which the brightness at the ranges of −45 degrees to −75 degrees and +45 degrees to +75 degrees at x-axis are greatly improved comparing to the reference brightness of a half sphere shaped packaging structure. Namely, the brightness of the packaging structure 224 of FIG. 5A is improved at the view of angle at about −75 degrees to about +75 degrees.

In some other embodiments, as shown in FIG. 6A, the packaging structure 224 is a half-cylinder symmetric along y-axis and has a concave surface along the y-axis, which can be referred as has two convex surfaces along x-axis. The corresponding simulation light field is shown in FIG. 6B. The light emitting angle of the packaging structure 224 of FIG. 6A is in a range from about −30 degrees to about −45 degrees, or about +30 degrees to about +45 degrees, and the brightness at the ranges of −70 degrees to −85 degrees and +70 degrees to +85 degrees are improved comparing to the reference brightness of a half sphere shaped packaging structure.

As shown in FIGS. 5A, 5B and FIGS. 6A, 6B, by shaping the shape of the packaging structure 224 to predetermined shape, the light-emitting angle of the packaging structure 224 can be tuned to satisfy different zones of the curve stereoscopic display, thereby improving brightness uniformity of the curve stereoscopic display.

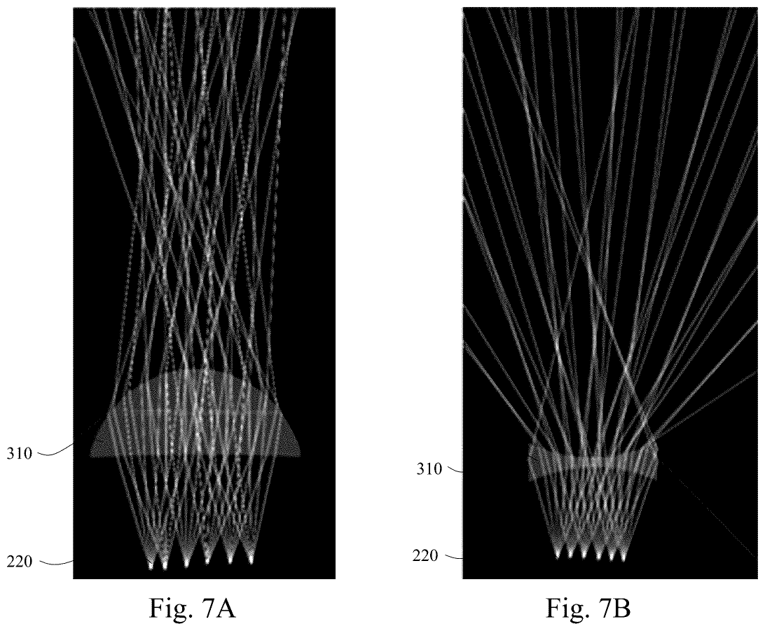

Reference is made to FIGS. 7A and 7B, which are optical simulation views of the optical lens of the curve stereoscopic display according to different embodiments of the disclosure. As mentioned previously, the optical lens 310 is disposed on the corresponding group of light-emitting units 220 such as the light-emitting units 220 emitting right-eye RGB image light and left-eye RGB image light. The optical lens 310 is configured to separate the right-eye image and left-eye image and further tune light paths of the light-emitting units 220. As shown in FIG. 7A, the optical lens 310 has a positive diopter such as a convex lens, the light emitted from the light-emitting units 220 is converged and the light emitting angle is reduced after passing the optical lens 310 having positive diopter. As shown in FIG. 7B, the optical lens 310 has a negative diopter such as a concave lens, the light emitted from the light-emitting units 220 is diverged and the light emitting angle is increased after passing the optical lens 310 having negative diopter.

As shown in FIGS. 7A and 7B, by designing the diopter of the optical lens 310, the light-emitting angle of leaving the optical lens 310 can be tuned to guide the light to predetermined image light path, which may solve the problem of failure or twist stereoscopic image of the curve stereoscopic display.

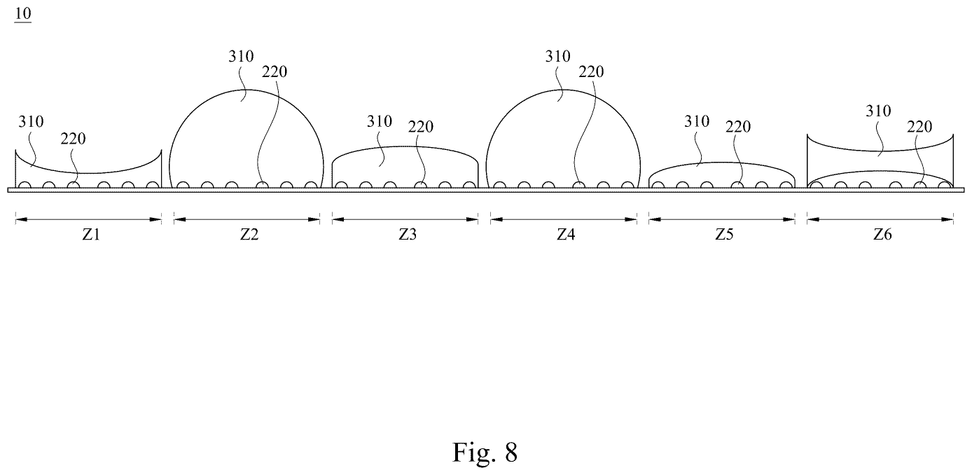

Reference is made to FIG. 8, which is a partial cross-sectional view of the curve stereoscopic display according to some embodiments of the disclosure. In some embodiments, the curve stereoscopic display 10 is divided into a plurality of zones such as zones Z1 to Z6. Each of the zones Z1 to Z6 is disposed with the group of light-emitting units 220 and the corresponding optical lens 310.

The packaging structures 224 of the light-emitting units 220 of each of the zones Z1 to Z6 are designed according to the light-emitting angle of the zone, and the diopter of the optical lens 310 of each of the zones Z1 to Z6 is designed according to the light path of the zone. Therefore, the optical designs of the packaging structures 224 and the optical lens 310 of different zones such as zones Z1 to Z6 can be different.

Reference is made back to FIG. 1. In some embodiments, after the light-emitting layer 200 and the parallax barrier 300 are disposed on the target carrier 100 with curved surface, the light-emitting layer 200 and the parallax barrier 300 may be deformed because of being stretched thereby affecting the stereoscopic display result. In some embodiments of the disclosure, not only the light path is adjusted by the designs of the packaging structures 224 and the optical lenses 310, but also adjust the output image of the light-emitting layer 200 by using software calibration based on the deformation amount of the stretched light-emitting layer 200 and the parallax barrier 300.

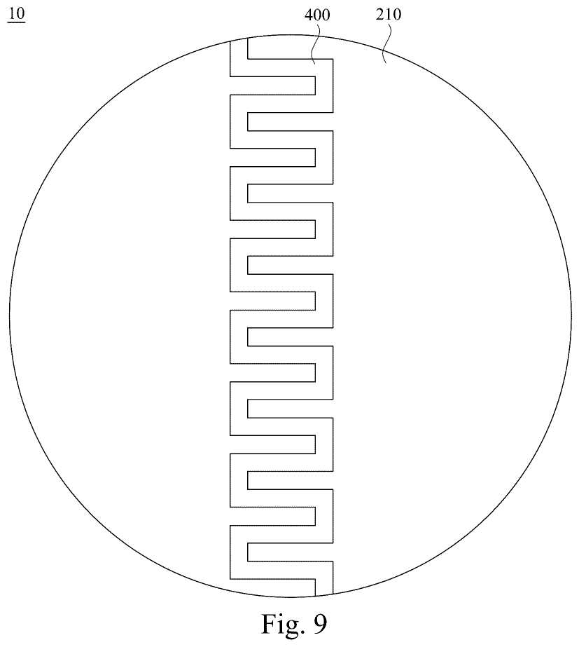

Reference is made to FIG. 9, which is a partial top view of the light-emitting layer of the curve stereoscopic display according to some embodiments of the disclosure. In some embodiments, the curve stereoscopic display 10 further includes a conductive pattern 400 disposed on the flexible substrate 210 of the light-emitting layer 200. The conductive pattern 400 can be meandrous shape, S shape, Z shape, or any other suitable zigzag pattern. In some embodiments, the conductive pattern 400 is a continuous pattern having uniform line width. In some other embodiments, the conductive pattern 400 is a continuous pattern having partial increased line width, to enhance partial stress tolerance.

Because the resistance of the conductive pattern 400 is directly related to its stretching ratio, such as the resistance of the conductive pattern 400 is increased when the stretching ratio of the conductive pattern 400 is increased, a relation table of the stretching ratio and the corresponding resistance of the conductive pattern can be established by pre-experiments. Therefore, the stretching ratio of the conductive pattern 400 can be obtained by measuring the resistance of the conductive pattern 400, thereby further obtaining the deformation amount of the curve stereoscopic display 10.

In some embodiments, the stretching ratio of the conductive pattern 400 is X, and X is in a range of 0.5%≤X≤80%, preferably X is in a range of 3%≤X≤40%. The stretching ratio X is the elongated amount/original length.

The resistance of the conductive pattern 400 not only relates to its stretching ratio, but relates to design of the conductive pattern 400. For example, the conductive pattern 400 having wider line width has gentle variation between the resistance and the stretching ratio, and the conductive pattern 400 having narrower line width has intense variation between the resistance and the stretching ratio. Additionally, the variation between the resistance and the stretching ratio of the conductive pattern 400 also relates to different shape designs, different total lengths, and different thermal process temperatures.

For example, with the same zigzag length of the conductive patterns 400, the total length of the conductive pattern 400 having zigzag shape is longer than the total length of the conductive pattern 400 having Z shape, and the total length of the conductive pattern 400 having Z shape is longer than the total length of the conductive pattern 400 having S shape. Therefore, the variation rate between the resistance and the stretching ratio of the conductive patterns 400 of zigzag shape, Z shape, and S shape are not different in the same layout area.

For example, after performing a 30 minutes thermal process under 50° C., the conductive patterns 400 with 450 μm line width has about zero resistance variation when the stretching ratio is 10%; the conductive patterns 400 with 450 μm line width has a resistance variation of about 0.07 to 0.09 Ω/μm when the stretching ratio is 20%; the conductive patterns 400 with 450 μm line width has a resistance variation of about 0.01 to 0.18 Ω/μm when the stretching ratio is 30%. The conductive patterns 400 with 300 μm line width has a resistance variation of about 0.05 to 0.08 Ω/μm when the stretching ratio is 10%; the conductive patterns 400 with 300 μm line width has a resistance variation of about 0.09 to 0.12 Ω/μm when the stretching ratio is 20%; the conductive patterns 400 with 300 μm line width has a resistance variation of about 0.20 to 0.30 Ω/μm when the stretching ratio is 30%. The conductive patterns 400 with 150 μm line width has a resistance variation of about 0.10 to 0.18 Ω/μm when the stretching ratio is 10%; the conductive patterns 400 with 150 μm line width has a resistance variation of about 0.18 to 0.35 Ω/μm when the stretching ratio is 20%; the conductive patterns 400 with 150 μm line width has a resistance variation of about 0.20 to 0.40 Ω/μm when the stretching ratio is 30%.

For example, after performing a 30 minutes thermal process under 100° C., the conductive patterns 400 with 450 μm line width has a resistance variation of about 0.01 to 0.05 Ω/μm when the stretching ratio is 10%; the conductive patterns 400 with 450 μm line width has a resistance variation of about 0.02 to 0.06 Ω/μm when the stretching ratio is 20%; the conductive patterns 400 with 450 μm line width has a resistance variation of about 0.05 to 0.08 Ω/μm when the stretching ratio is 30%. The conductive patterns 400 with 300 μm line width has a resistance variation of about 0.02 to 0.05 Ω/μm when the stretching ratio is 10%; the conductive patterns 400 with 300 μm line width has a resistance variation of about 0.03 to 0.06 Ω/μm when the stretching ratio is 20%; the conductive patterns 400 with 300 μm line width has a resistance variation of about 0.05 to 0.08 Ω/μm when the stretching ratio is 30%. The conductive patterns 400 with 150 μm line width has a resistance variation of about 0.05 to 0.08 Ω/μm when the stretching ratio is 10%; the conductive patterns 400 with 150 μm line width has a resistance variation of about 0.06 to 0.10 Ω/μm when the stretching ratio is 20%; the conductive patterns 400 with 150 μm line width has a resistance variation of about 0.08 to 0.25 Ω/μm when the stretching ratio is 30%.

For example, after performing a 30 minutes thermal process under 150° C., the conductive patterns 400 with 450 μm line width has a resistance variation of about 1 to 10 Ω/μm when the stretching ratio is 10%; the conductive patterns 400 with 450 μm line width has a resistance variation of about 3 to 5 Ω/μm when the stretching ratio is 20%; the conductive patterns 400 with 450 μm line width has a resistance variation of about 8 to 10 Ω/μm when the stretching ratio is 30%. The conductive patterns 400 with 300 μm line width has a resistance variation of about 3 to 7 Ω/μm when the stretching ratio is 10%; the conductive patterns 400 with 300 μm line width has a resistance variation of about 4 to 8 Ω/μm when the stretching ratio is 20%; the conductive patterns 400 with 300 μm line width has a resistance variation of about 5 to 15 Ω/μm when the stretching ratio is 30%. The conductive patterns 400 with 150 μm line width has a resistance variation of about 5 to 13 Ω/μm when the stretching ratio is 10%; the conductive patterns 400 with 150 μm line width has a resistance variation of about 8 to 18 Ω/μm when the stretching ratio is 20%; the conductive patterns 400 with 150 μm line width has a resistance variation of about 15 to 40 Ω/μm when the stretching ratio is 30%. If the resistance variation is too strong, a line broken issue may be raised, the pattern design or the line width thereof is not suitable in the conductive patterns 400 of the curve stereoscopic display.

Based on the conductive pattern 400 designs including different line widths, different lengths, and different pattern shapes, the stretching ratio of the conductive pattern 400 can be obtained by measuring the resistance of the conductive pattern 400, and the deformation amount of the curve stereoscopic display 10 can be further obtained by the stretching ratio of the conductive pattern 400. The output image by the light-emitting layer 200 can be adjusted according to the deformation amount of the curve stereoscopic display 10, including adjusting at least one of display parameter of the curve stereoscopic display 10. For example, deformations of the curve stereoscopic display 10 include ΔX, ΔY, ΔZ of three axes in three-dimensional coordinate system, azimuth angle (θ) and polar angle (φ) of the spherical coordinate system and Δφ, Δθ before and after being stretched are send to software calibration to adjust the output image of the light-emitting layer 200. The light path of the output image is further tuned by the designed packaging structures and/or the designed parallax barrier, such that the light can be guided to the predetermined stereoscopic image position.

Additionally, in some other embodiments, the performance of stereoscopic image can be improved by image calibration software when the light-emitting layer 200 and the parallax barrier 300 are dynamic stretched or expendably stretched to be conformally cover the curve surface of the target carrier 100.

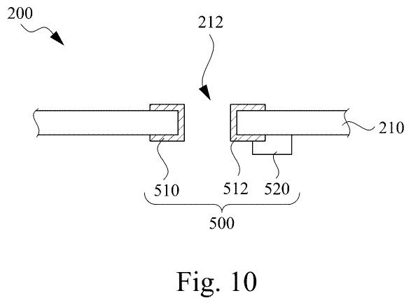

Reference is made to FIG. 10, which is a partial cross-sectional view of the light-emitting layer of the curve stereoscopic display according to some embodiments of the disclosure. In some embodiments, the curve stereoscopic display further includes a capacitor type feedback component 500 disposed in the flexible substrate 210, to obtain the deformation amount of the light-emitting layer 200 according to the variation of the capacitance provided by the capacitor type feedback component 500, and further use software calibration to adjust the output image of the light-emitting layer 200.

In some embodiments, the flexible substrate 210 includes a through hole 212. The capacitor type feedback component 500 includes a first electrode 510 and a second electrode 512 disposed on opposite side surfaces of the through hole 212, in which the first electrode 510 is not physically connected to the second electrode 512. The capacitor type feedback component 500 further includes a capacitance sensor 520 connected to the first electrode 510 or the second electrode 512. The capacitance sensor 520 is configured to detect the capacitance variation between the first electrode 510 and the second electrode 512.

For example, the diameter of the through hole 212 is increased when the stretching ratio of the light-emitting layer 200 is increased such that the distance between the first electrode 510 and the second electrode 512 is increased accordingly. The relation table of the stretching ratio and the corresponding capacitance can be established by pre-experiments. Therefore, the deformation amount of the light-emitting layer 200 can be obtained by measuring the capacitance, thereby further adjusting the output image of the light-emitting layer 200 by adjusting at least one of display parameter of the curve stereoscopic display 10. For example, deformations of the curve stereoscopic display 10 including ΔX, ΔY, ΔZ of three axes in three-dimensional coordinate system, azimuth angle (θ) and polar angle (φ) of the spherical coordinate system and Δφ, Δθ before and after being stretched can be obtain by the measured capacitance variation and are send to software calibration to adjust the output image of the light-emitting layer 200. The light path of the output image is further tuned by the designed packaging structures and/or the designed parallax barrier, such that the light can be guided to the predetermined stereoscopic image position. In some other embodiments, the performance of stereoscopic image can be improved by image calibration software.

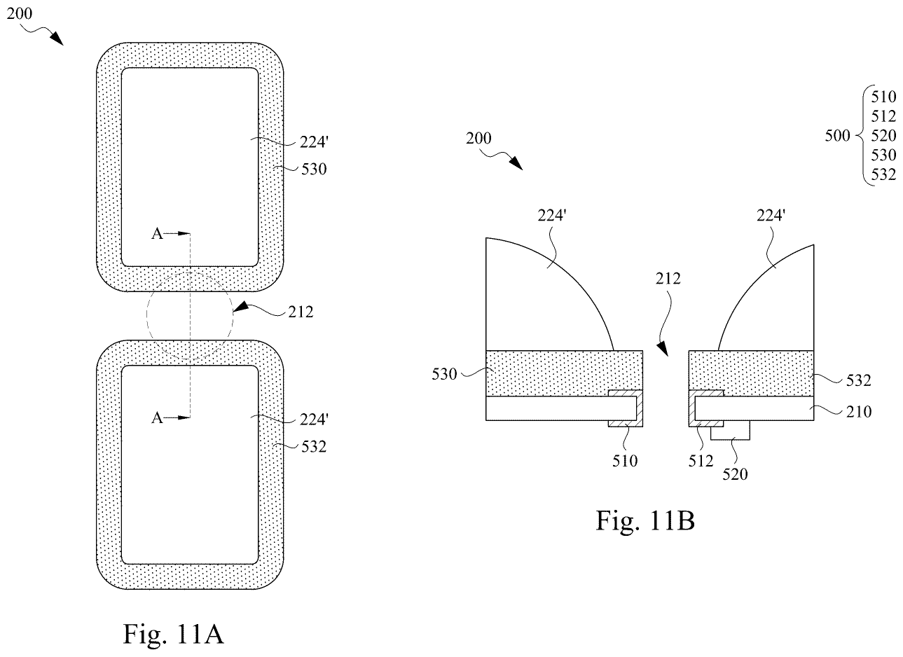

Reference is made to FIG. 11A and FIG. 11B, which are partial top view and cross-sectional view of the light-emitting layer of the curve stereoscopic display according to some embodiments of the disclosure, respectively, in which FIG. 11B is taken along the line A-A of FIG. 11A. In some embodiments, the capacitor type feedback component 500 includes the first electrode 510 and the second electrode 512 disposed on opposite side surfaces of the through hole 212, the capacitance sensor 520 connected to the first electrode 510 or the second electrode 512, and further includes a first piezoelectric material layer 530 and a second piezoelectric material layer 532 disposed opposite sides of the thought hole 212 and on a top surface of the flexible substrate 210. The first piezoelectric material layer 530 is connected to the first electrode 510. The second piezoelectric material layer 532 is connected to the second electrode 512. The first piezoelectric material layer 530 is not physically connected to the second piezoelectric material layer 532.

When the flexible substrate 210 is stretched and is bended or deformed, an external force is applied to the first piezoelectric material layer 530 and the second piezoelectric material layer 532 such that a potential difference is generated between the first piezoelectric material layer 530 and the second piezoelectric material layer 532. The potential difference between the first piezoelectric material layer 530 and the second piezoelectric material layer 532 further change the electric field distribution of the first electrode 510 and the second electrode 512 that are connected to the first piezoelectric material layer 530 and the second piezoelectric material layer 532, respectively. Therefore, the capacitance between the first electrode 510 and the second electrode 512 is not only changed by the distance therebetween but also changed by the potential difference between the first piezoelectric material layer 530 and the second piezoelectric material layer 532 so that the capacitance between the first electrode 510 and the second electrode 512 is more sensitive.

Additionally, in some embodiments, optionally, the material of the packaging structures 224′ is encapsulate liquid or gel which can be deformed by electrophoresis effect or polarizing effect induced by voltage or current. The curve stereoscopic display 10 can further change the light-emitting angle of each of the packaging structures 224′ by introducing the capacitor type feedback component 500.

Each of the packaging structures 224′ is disposed on one or more light-emitting components 222. The first piezoelectric material layer 530 and the second piezoelectric material layer 532 respectively surround or partially surround the corresponding packaging structure 224′ to serve as shape adjusting pads of the packaging structure 224′. The potential difference is generated between the first piezoelectric material layer 530 and the second piezoelectric material layer 532 when the flexible substrate 210 is stretched, and the current and/or voltage applied to the packaging structure 224′ are also changed. The shape of the packaging structure 224′ is modified accordingly, thereby achieving the purpose of dynamic adjusting the light-emitting angle of the packaging structure 224′.

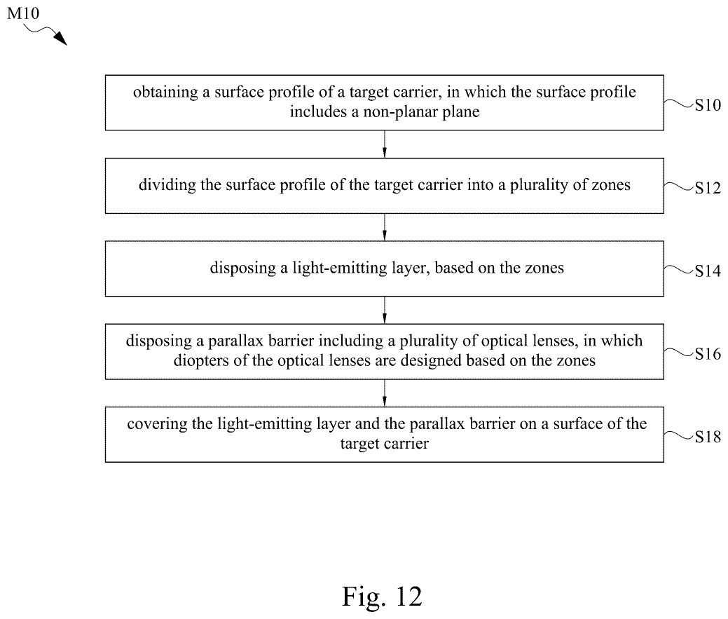

Reference is made to FIG. 12, which is a flow chart of a method of manufacturing the curve stereoscopic display according to some embodiments of the disclosure. The method of manufacturing the curve stereoscopic display M10 begins at step S10, including obtaining a surface profile of a target carrier, in which the surface profile includes a non-planar plane. In some embodiments, step S10 includes using optical instrument to three-dimensional scan the surface profile of the target carrier, and the surface profile of the target carrier is send to the process for the following processing processes.

Then, step S12 includes dividing the surface profile of the target carrier into a plurality of zones. Each of the zones contains at least one pixel of the curve stereoscopic display.

Step S14 includes disposing a light-emitting layer, based on the zones. The light-emitting layer includes a flexible substrate and a plurality of light-emitting units disposed on the flexible substrate. Each of the light-emitting units includes at least one light-emitting component and a packaging structure disposed on the light-emitting component. In some embodiments, the light-emitting angle of each of the packaging structures is designed according to the corresponding zone thereby improving brightness uniformity of the curve stereoscopic display.

In some embodiments, the material of the packaging structures can be aforementioned organic materials, inorganic materials, or other suitable materials. The step S14 of disposing a light-emitting layer includes such as defining the shape of each of the packaging structures by lithography processes. In some embodiments, the material of the packaging structures can be encapsulate liquid or gel, and the step S14 of disposing a light-emitting layer includes disposing piezoelectric material layers on the flexible substrate, in which the piezoelectric material layers partially surrounds the corresponding packaging structures. In some embodiments, the packaging structures can be multilayer structures. For example, a composite film including one or more of transparent water resist layer or diffraction layer can be further defined on the encapsulate liquid or gel, in which the material of the composite film can be transparent organic material, transparent inorganic material, or transparent composite material.

Step S16 includes disposing a parallax barrier. The parallax barrier includes a plurality of optical lenses, and the diopters of the optical lenses are designed based on the zones. For example, the optical lens having positive diopter can be utilized to converge light, and the optical lens having negative diopter can be utilized to diverge light. The parallax barrier not only separates the right-eye image and the left-eye image, but also guides the light to the predetermined image position such that the curve stereoscopic display can successfully display stereoscopic image. The light path can be tuned by designing the packaging structures and/or the parallax barrier to fit the requirement of curve stereoscopic display. Additionally, at least one of display parameters of the curve stereoscopic display is adjusted according to the feedback of the deformation including ΔX, ΔY, ΔZ of three axes in three-dimensional coordinate system, azimuth angle (θ) and polar angle (φ) of the spherical coordinate system and Δφ, Δθ before and after being stretched. In some other embodiments, the performance of stereoscopic image can be improved by image calibration software.

Finally, step S18 includes covering the light-emitting layer and the parallax barrier on a surface of the target carrier. The surface profile of the target carrier includes non-planar surface, and the light-emitting layer and the parallax barrier are covered on of the target carrier along the non-planar surface. In some embodiments, the light-emitting layer and the parallax barrier are conformally adhered on the surface of the target carrier.

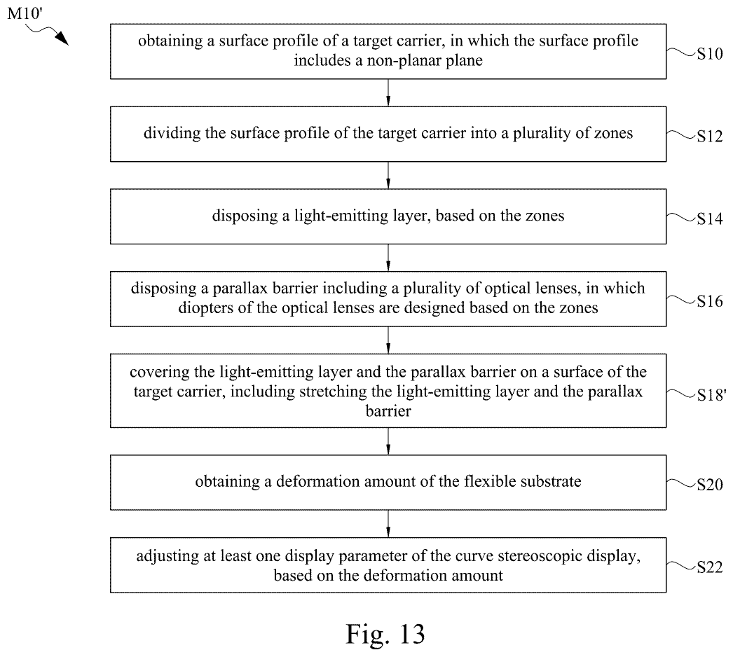

Reference is made to FIG. 13, which is a flow chart of a method of manufacturing the curve stereoscopic display according to some other embodiments of the disclosure. In some embodiments, the step S18′ of the method of manufacturing the curve stereoscopic display M10′ includes stretching the light-emitting layer and the parallax barrier. The relative position between the light-emitting units and the optical lenses are remained the same before and after stretching the light-emitting layer and the parallax barrier.

The method of manufacturing the curve stereoscopic display M10′ further includes step S20, including obtaining a deformation amount of the flexible substrate. For example, step S20 may include measuring a resistance of a conductive pattern disposed on the flexible substrate, and the deformation amount of the flexible substrate can be obtained by the measured resistance. Alternatively, step S250 may include measuring a capacitance of capacitor type feedback component that is disposed on the flexible substrate, and the deformation amount of the flexible substrate can be obtained by the measured capacitance.

Finally, step S22 includes operating the processor based on the deformation amount of the flexible substrate, to adjust at least one display parameter of the curve stereoscopic display. For example, deformations of the curve stereoscopic display 10 including ΔX, ΔY, ΔZ of three axes in three-dimensional coordinate system, azimuth angle (θ) and polar angle (φ) of the spherical coordinate system and Δφ, Δθ before and after being stretched are obtained as feedback to compensate deformation due to stretching the light-emitting layer and the parallax barrier and to output adjusted image. Additionally, the performance of stereoscopic image can be improved by image calibration software.

As mentioned above, the curve stereoscopic display and fabricating method thereof of the embodiments of the disclosure can improve the brightness uniform by designing the light-emitting angles of the packaging structures of the light emitting layer, and adjusting light path emitted by the light-emitting layer by designing the optical lenses of the parallax barrier to guide the light to the predetermined image position such that the curve stereoscopic display can successfully display stereoscopic image.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims and their equivalents.

1. A curve stereoscopic display comprising:
a target carrier having a surface, the surface having a first zone and a second zone, wherein a normal direction of the first zone is different from a normal direction of the second zone;
a light-emitting layer comprising:
a flexible substrate covering the surface of the target carrier; and
a plurality of light-emitting units disposed on the flexible substrate, wherein each of the light-emitting units comprises a light-emitting component and a packaging structure on the light-emitting component, and the light-emitting units comprise a first group of light-emitting units on the first zone and a second group of light-emitting units on the second zone; and
a parallax barrier disposed on the light-emitting layer, wherein the parallax barrier is spaced from the light-emitting layer, wherein the parallax barrier comprises a plurality of optical lenses and a plurality of first elastic pieces disposed to interconnect the optical lenses, and the optical lenses comprise a first optical lens on the first zone and a second optical lens on the second zone, wherein the first optical lens is configured to adjust a light path of the first group of light-emitting units, and the second optical lens is configured to adjust a light path of the second group of light-emitting units, wherein a diopter of the first optical lens is different from a diopter of the second optical lens.

2. The curve stereoscopic display of claim 1, wherein the light-emitting layer further comprises:
a plurality of control boards disposed on the flexible substrate, wherein the light-emitting units are disposed on the control boards; and
a plurality of second elastic pieces disposed to interconnect the control boards.

3-5. (canceled)

6. The curve stereoscopic display of claim 1, wherein a distance between the first group of light-emitting units and the first optical lens is same as a distance between the second group of light-emitting units and the second optical lens.

7. The curve stereoscopic display of claim 1, wherein a light-emitting angle provided by the packaging structures of the first group of light-emitting units is different from a light-emitting angle provided by the packaging structures of the second group of light-emitting units.

8. The curve stereoscopic display of claim 1, further comprising a conductive pattern disposed on the flexible substrate, wherein a resistance of the conductive pattern is varied response to a deformation of the flexible substrate.

9. The curve stereoscopic display of claim 1, further comprising a capacitor type feedback component disposed in the flexible substrate.

10. The curve stereoscopic display of claim 9, wherein the flexible substrate comprising a through hole, and the capacitor type feedback component comprises:
a first electrode and a second electrode disposed on opposite side surfaces of the through hole, wherein the first electrode is not physically connected to the second electrode; and
a capacitance sensor connected to the first electrode or the second electrode.

11. The curve stereoscopic display of claim 10, wherein the capacitor type feedback component comprises:
a first piezoelectric material layer and a second piezoelectric material layer disposed on a top surface of the flexible substrate and disposed on opposite sides of the through hole, wherein the first piezoelectric material layer is connected to the first electrode, the second piezoelectric material layer is connected to the second electrode, and the first piezoelectric material layer is not physically connected to the second piezoelectric material layer.

12. The curve stereoscopic display of claim 11, wherein a material of the packaging structures comprises encapsulate liquid or gel, and the first piezoelectric material layer and the second piezoelectric material layer at least partially surrounding the packaging structures, respectively.

13. A method of manufacturing a curve stereoscopic display comprising:
obtaining a surface profile of a target carrier, wherein the surface profile comprises a non-planar plane;
dividing the surface profile into a plurality of zones;
disposing a light-emitting layer, based on the zones, the light-emitting layer comprises a flexible substrate and a plurality of light-emitting units disposed on the flexible substrate, wherein each of the light-emitting units comprises a light-emitting component and a packaging structure on the light-emitting component;
disposing a parallax barrier, wherein the parallax barrier comprises a plurality of optical lenses and a plurality of elastic pieces disposed to interconnect the optical lenses, and diopters of the optical lenses are designed based on the zones; and
covering the light-emitting layer and the parallax barrier on a surface of the target carrier, wherein the parallax barrier is spaced from the light-emitting layer.

14. The method of manufacturing the curve stereoscopic display of claim 13, further comprising:
measuring a resistance of a conductive pattern that is disposed on the flexible substrate to obtain a deformation amount of the flexible substrate; and
adjusting at least one display parameter of the curve stereoscopic display, based on the deformation amount.

15. The method of manufacturing the curve stereoscopic display of claim 13, further comprising:
measuring a capacitance of a capacitor type feedback component that is disposed on the flexible substrate to obtain a deformation amount of the flexible substrate; and
adjusting at least one display parameter of the curve stereoscopic display, based on the deformation amount.

16. The method of manufacturing the curve stereoscopic display of claim 13, wherein a light-emitting angle of each of the packing structures is designed based on the zones.

17. The method of manufacturing the curve stereoscopic display of claim 13, wherein covering the light-emitting layer and the parallax barrier on the surface of the target carrier comprises stretching the light-emitting layer and stretching the parallax barrier.

18. The method of manufacturing the curve stereoscopic display of claim 17, wherein a relative position between the light-emitting elements and the optical lenses remains the same, before and after stretching the light-emitting layer and stretching the parallax barrier.

19. The method of manufacturing the curve stereoscopic display of claim 13, wherein a material of the packaging structures is an organic material, and the disposing the light-emitting layer comprises defining shapes of the packaging structures by performing a lithography process.

20. The method of manufacturing the curve stereoscopic display of claim 13, wherein a material of the packaging structures comprises encapsulate liquid or gel, and the disposing the light-emitting layer comprises disposing a plurality of piezoelectric material layers on the flexible substrate, and the piezoelectric material layers at least partially surrounding the packaging structures, respectively.
